(19) United States
(12) Patent Application Publication
(10) Pub. No.: US 2003/0059718 A1
(43) Pub. Date: Mar. 27, 2003

(54) Method for forming a contact window in a semiconductor device

(75) Inventors: Dev Alok, Danbury, CT (US); Juanita A. Barone, Mohegan Lake, NY (US); Regina Conrad, Ossining, NY (US)

Correspondence Address: STEVEN R. BIREN, Corporate Patent Counsel, Philips Electronics North America Corporation, 580 White Plains Road, Tarrytown, NY, 10591, US

(73) Assignee: KONINKLIJKE PHILIPS ELECTRONICS N.V.

(21) Appl. No.: 09/961,997

(22) Filed: Sep. 24, 2001

(51) Int. Cl. G03F 7/00

(52) U.S. Cl. 430/311; 430/313

(57) ABSTRACT

A method for forming a contact window in a semiconductor device is provided. Specifically, the present invention provides a method for removing a passivation layer over a pad metal without using a photo mask. The method generally comprises applying a photo resist layer over a passivation layer, which itself is positioned over a substrate and a pad metal. A portion of the photo resist layer is then developed using ultraviolet light. The developed portion is etched away with a developer to reveal the passivation layer over the pad metal, which is subsequently removed to yield a contact window.

### BACKGROUND OF THE INVENTION

1. Technical Field

The present invention generally relates to a method for forming contact windows in a semiconductor device. In particular, the present invention relates to a method for forming a contact window in a semiconductor device without using a photo mask.

2. Background Art

For several decades, semiconductor devices have been an advancing technology used in electronic devices. Typical semiconductor devices include, among other things, a substrate, a pad metal mounted on the substrate, and a passivation layer positioned over both the substrate and the pad metal. In general, the substrate can be silicon or silicon carbide, while the passivation layer can be an oxide such as silicon dioxide. Usually, the final step in producing a semiconductor device is to form/open contact windows by removing the portion of the passivation layer that is over the pad metal. By removing the passivation layer over the pad metal, the top surface of the pad metal can be exposed and subsequently used for making an electrical contact.

Current methods for removing the passivation layer over the pad metal either utilize a photo mask, or require a precise etching process. In the case of the former, the use of a photo mask helps ensure that the portion of the passivation layer that is not over the pad metal (i.e., is over the substrate) is left intact. However, using a photo mask can considerably add to the expense of producing the device. In general, the ability to eliminate one photo mask from the production process can reduce the total production cost by as much as fifty percent. In the case of a precise etching process, expensive equipment and/or large amounts of time are generally required and poor yield often results.

In view of the forgoing, there exists a need for a more efficient method for forming contact windows in a semiconductor device that does not require an additional photo mask. Specifically, a need exists for a method that allows the passivation layer to be removed over the pad metal without using a photo mask or a precise etching process.

### SUMMARY OF THE INVENTION

The present invention solves the problems with existing methods by providing a method for forming a contact window in a semiconductor device having a substrate, a pad metal mounted on the substrate, and a passivation layer positioned over both the pad metal and the substrate. In general, the method includes applying a photo resist layer over the passivation layer. The applied photo resist layer is then flood exposed to ultra violet light for a predetermined period of time. This causes a portion of the photo resist layer directly on top of to become fully developed while leaving the photo resist elsewhere partially undeveloped. The fully developed portion is then etched away with a developer to reveal the passivation layer over the pad metal. The revealed passivation layer is subsequently removed, using the undeveloped photo resist as a mask, to form a contact window.

According to a first aspect of the present invention, a method for forming a contact window in a semiconductor device having a substrate, a pad metal mounted on the substrate, and a passivation layer positioned over both the pad metal and the substrate is provided. The method comprises the steps of: (1) applying a photo resist layer over the passivation layer; (2) developing a portion of the applied photo resist layer using ultraviolet light; (3) etching away the developed portion to reveal the passivation layer over the pad metal; and (4) forming a contact window by removing the revealed passivation layer.

According to a second aspect of the present invention, a method for forming a contact window in a semiconductor device is provided. The method comprises the steps of: (1) providing a semiconductor device having a substrate, a pad metal mounted on the substrate, and a passivation layer positioned over both the substrate and the pad metal; (2) applying a photo resist layer over the passivation layer; (3) developing a portion of the applied photo resist layer using incident ultraviolet light and its reflection from the pad metal; (4) etching away the developed portion to reveal the passivation layer over the pad metal; and (5) forming a contact window by removing the revealed passivation layer over the pad metal.

According to a third aspect of the present invention, a method for forming a contact window in a semiconductor device is provided. The method comprises the steps of: (1) providing a semiconductor device having a substrate, a pad metal mounted on the substrate, and a passivation layer over both the substrate and the pad metal; (2) applying a photo resist layer over the passivation layer; (3) developing a portion of the applied photo resist layer using incident ultraviolet light and its reflection from the pad metal; (4) etching away the developed portion to reveal the passivation layer over the pad metal; (5) baking an undeveloped portion of the photo resist layer; (6) forming a contact window by removing the revealed passivation layer over the pad metal; and (7) removing the baked portion of the photo resist layer.

According to a fourth aspect of the present invention, a method for forming a contact window in a semiconductor device is provided. The method comprises the steps of: (1) providing a semiconductor device having a substrate, a pad metal mounted on the substrate, and a passivation layer over both the substrate and the pad metal; (2) applying a photo resist layer over the passivation layer; (3) developing a portion of the applied photo resist layer using ultraviolet light for a predetermined period of time, wherein the predetermined period of time is based upon a thickness of the photo resist layer and a difference in reflection coefficients of the pad metal and the substrate; (4) etching away the developed portion to expose the passivation layer over the pad metal; (5) baking an undeveloped portion of the photo resist layer over the substrate; (6) forming a contact window by removing the passivation layer over the pad metal; and (7) removing the baked portion over the substrate.

Therefore, the present invention provides a method for forming a contact window in a semiconductor without using a photo mask.

### BRIEF DESCRIPTION OF THE DRAWINGS

These and other features and advantages of this invention will be more readily understood from the following detailed description of the various aspects of the invention taken in conjunction with the accompanying drawings in which:

FIG. 1 depicts a first exemplary semiconductor device that has a substrate, a pad metal mounted on the substrate, and a passivation layer positioned over both the pad metal and the substrate.

FIG. 2 depicts the device of FIG. 1 with a photo resist layer applied over the passivation layer.

FIG. 3 depicts the device of FIG. 2 after a portion of the photo resist layer has been developed using incident and reflected rays of ultraviolet light.

FIG. 4 depicts the device of FIG. 3 after the developed portion has been etched away.

FIG. 5 depicts the device of FIG. 4 after the passivation layer over the pad metal has been removed using an undeveloped portion of the photo resist layer as a mask.

FIG. 6 depicts the device of FIG. 5 after the undeveloped portion of the photo resist layer over the substrate has been removed.

FIG. 7 depicts a second exemplary semiconductor device.

It is noted that the drawings of the invention are not necessarily to scale. The drawings are merely schematic representations, not intended to portray specific parameters of the invention. The drawings are intended to depict only typical embodiments of the invention, and therefore should not be considered as limiting the scope of the invention. In the drawings, like numbering represents like elements.

### DETAILED DESCRIPTION OF THE DRAWINGS

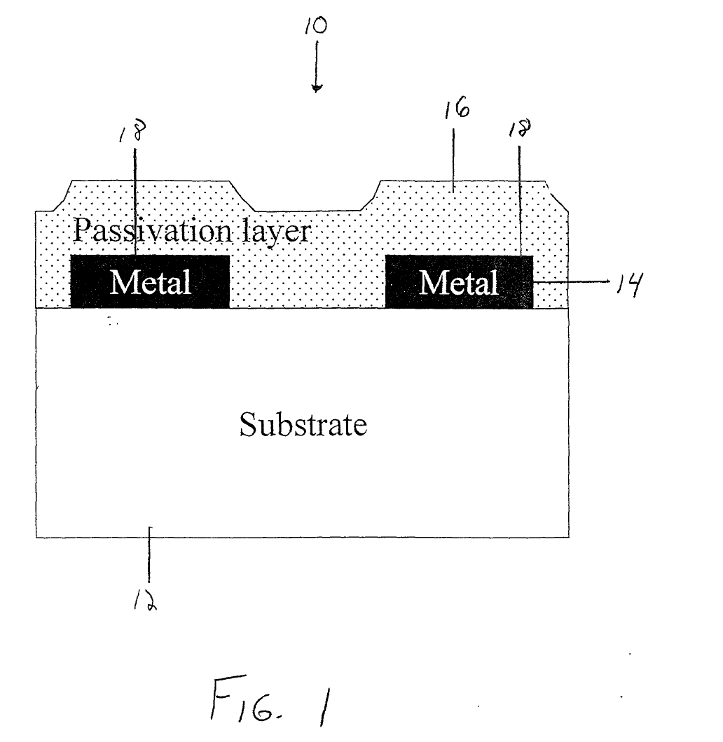

Referring now to FIG. 1, an exemplary semiconductor device 10 is shown. As depicted, device 10 includes substrate 12, pad metal 14 mounted on substrate 12, and passivation layer 16 positioned over both substrate 12 and pad metal 14. Device 10 can be any type of semiconductor device known in the art and is not intended to be a limiting feature of the present invention. For example, substrate 12 can be silicon carbide, pad metal 14 could be copper or aluminum, and passivation layer 16 could be an oxide layer such as silicon dioxide. Moreover, it should be understood that the process used to produce device 10 is not intended to be a limiting feature of the present invention. For example, pad metal 14 and passivation layer 16 could be deposited via evaporation and chemical vapor deposition, respectively.

The present invention comprises a method for forming/opening contact windows in device 10 without using a photo mask. Specifically, the present invention provides a method for removing passivation layer 16 over pad metal 14 so that a top surface 18 thereof is revealed and can be used to make an electrical contact.

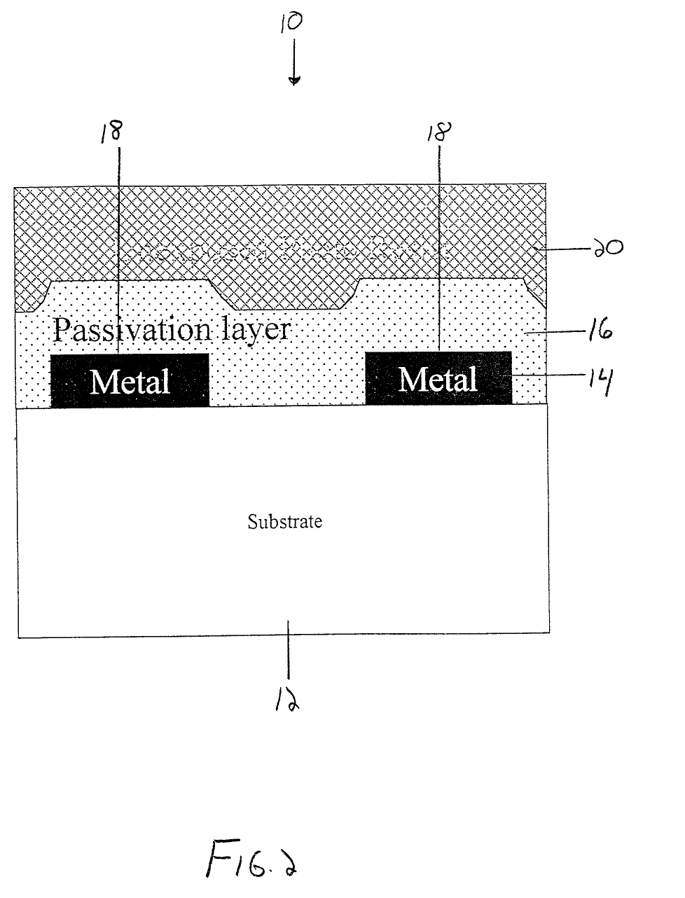

In general, the first step in forming a contact window is to apply a photo resist layer 20 over passivation layer 16, as shown in FIG. 2. Preferably, photo resist layer 20 is a positive photo resist layer that softens or develops when exposed to ultraviolet light. In addition, photo resist layer 20 could be applied over passivation layer 16 using any known means, such as spinning. Once photo resist layer 20 has been applied, the entire layer is then flood exposed to ultraviolet light for a predetermined period of time. This will result in a portion(s) of photo resist layer 20 becoming “fully developed.” The time period for which photo resist layer 20 is flood exposed to ultraviolet light under the present invention depends on the thickness of photo resist layer 20 and the difference in reflection coefficients between substrate between pad metal 14 and substrate 12. With respect to the former, the greater the thickness of photo resist layer 20, the greater the required time period of exposure. With respect to the latter, the greater the difference in reflectivity between pad metal 14 and substrate 12, the lesser the required time period of exposure.

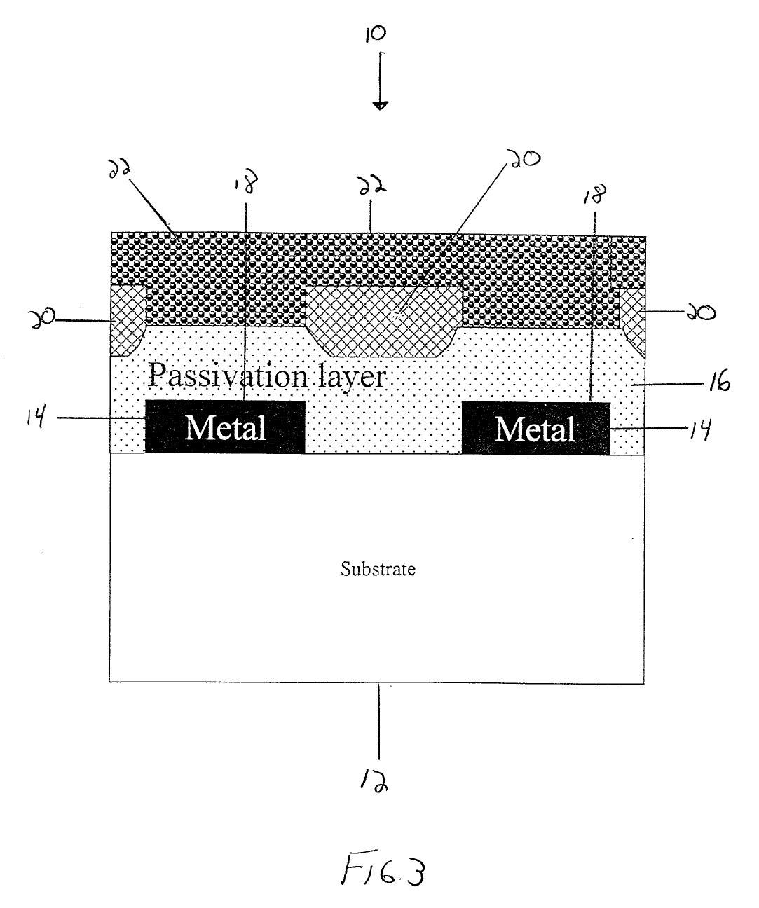

Due to the reflectivity of pad metal 14, the intensity of the ultraviolet light will be higher on top surface 18 of pad metal 14. Thus, as shown in FIG. 3, the entire photo resist layer over pad metal 18 is fully developed 22. Conversely, because the intensity of the ultraviolet light is not as great over substrate 12, a portion of the photo resist layer over substrate 12 will remain undeveloped 20. Thus, the photo resist layer over substrate 12 comprises two portions, developed 22 and undeveloped 20. Hence, due to reflectivity of pad metal 14, pinpointing the ultraviolet light over the pad metal 14 was not required. Once the necessary portion of photo resist layer (i.e., over pad metal 14) has been developed 22, all developed photo resist 22 will be etched away with a developer. The end result is preferably removal of the entire photo resist layer over pad metal 14 to reveal passivation layer 16 over pad metal 14, and thinning of the photo resist layer elsewhere (i.e., over substrate 12). Preferably the developer is diluted to slow the photo resist removal process and comprises chemical OCG-932, Dilution 3:2:developer:water available from OCG.

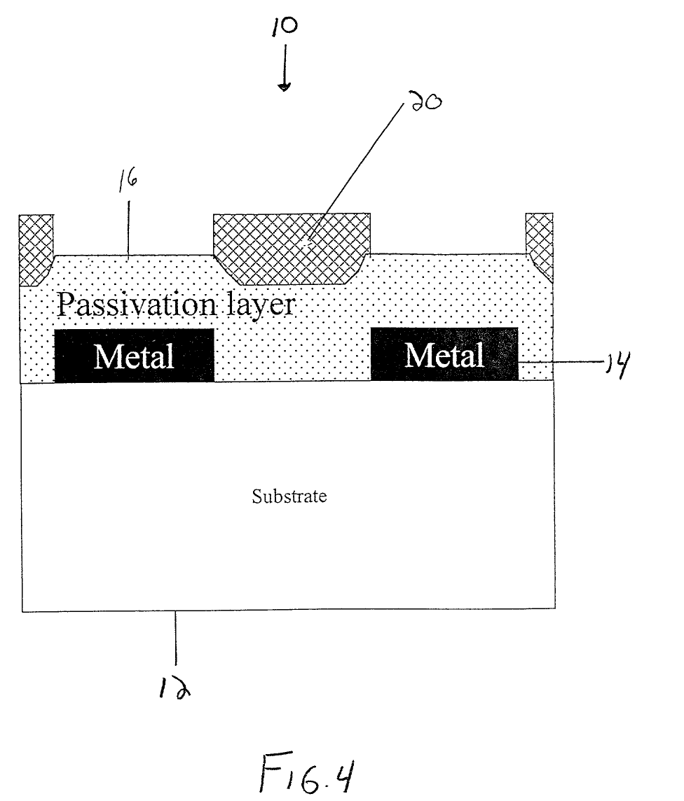

Referring to FIG. 4, device 10 is depicted with the developed photo resist etched away. As shown, all photo resist over pad metal 14 has been etched away with developer to reveal passivation layer 16. Conversely, undeveloped photo resist 20 remains over substrate 12. As indicated above, not all of photo resist layer over substrate 12 is developed because the intensity of the ultraviolet light is not as great over substrate 12 as it is over pad metal 14. Thus, undeveloped portion 20 is not softened by the ultraviolet light and is not subsequently removed by the developer. On some occasions, a thin film of photo resist may remain over pad metal 14 because the photo resist layer was not fully developed and/or etched sufficiently. In such an event, the remaining film of photo resist layer over pad metal 14 could be removed with a chemical etchant such as oxygen plasma.

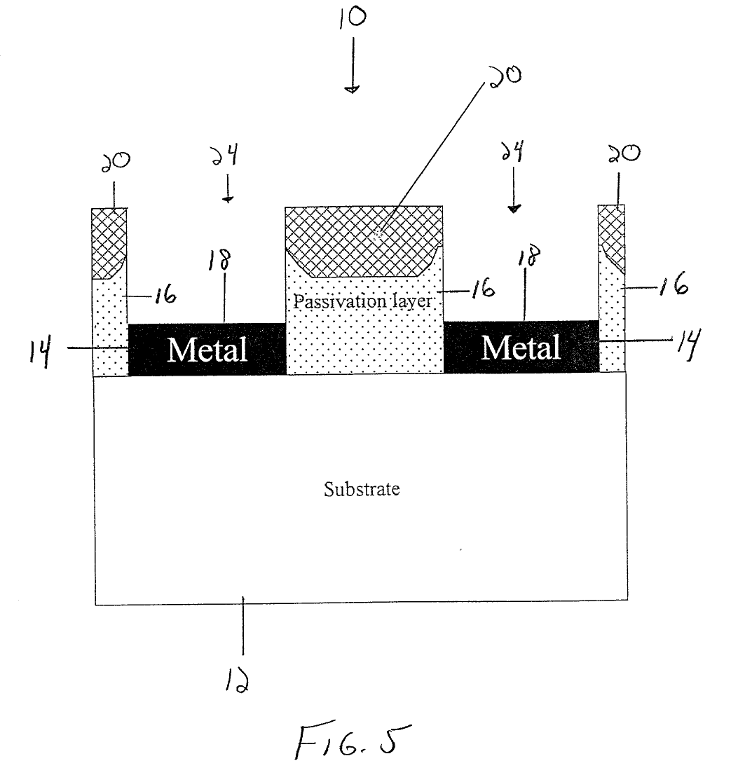

After all developed photo resist 22 has been removed, the remaining undeveloped photo resist 20 is hard baked so that revealed passivation layer 16 over pad metal 14 can be removed to yield contact window 24, as shown in FIG. 5. Removal of passivation layer 16 is preferably accomplished with wet etching in hydrogen fluoride or reactive ion etching. In this instance, hard baked undeveloped photo resist 20 acts as a mask that shields passivation layer 16 over substrate 12 from being removed. Under previous methods, passivation layer 16 over the substrate 12 is protected using a photo mask that has to be aligned with pad metal 18, which adds to the expense and/or time in producing device 10. The removal of passivation layer over pad metal 14 is referred to as forming/opening a contact window 24 because top surface 18 of pad metal is exposed. Once exposed, top surface 18 of pad metal 14 can be treated and/or used to form an electrical contact.

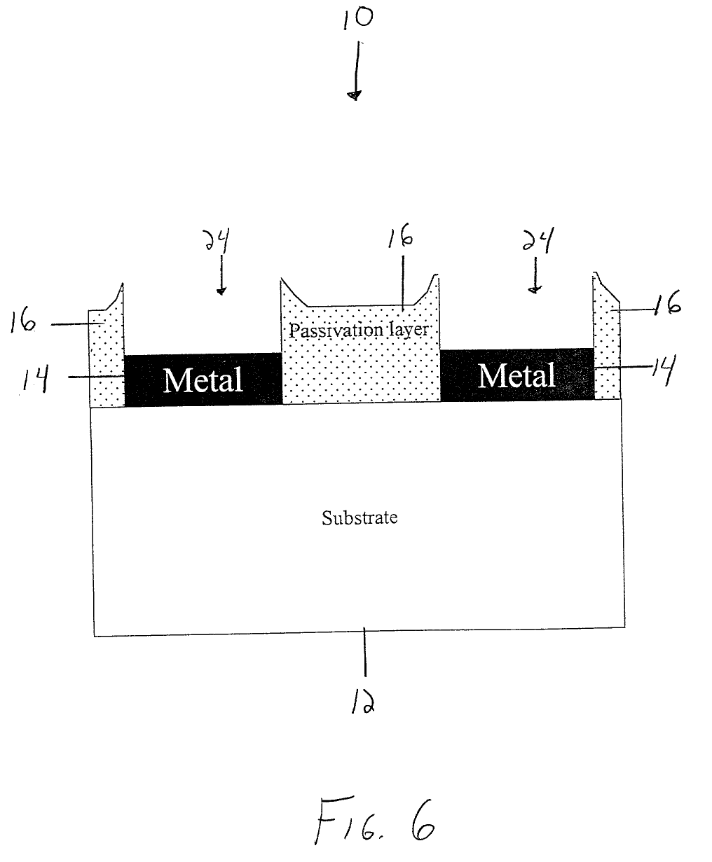

After contact window 24 has been formed, the remaining hard baked undeveloped photo resist 20 (i.e., over substrate 12) can be removed. As shown in FIG. 6, this yields device 10 having substrate 12, pad metal 14, window contacts 24 and passivation layer 16 overlying substrate 12. Preferably, the remaining photo resist layer is removed with an organic solution such as N-Methylpyrrolidinone (NMP) available from Mallinckrodt Baker, Inc. so that pad metal 14 will not be harmed.

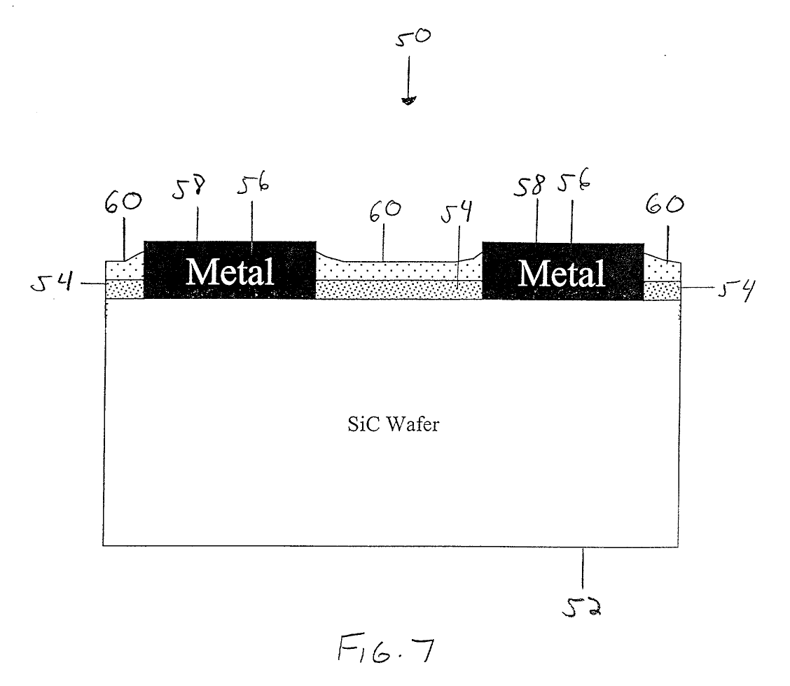

Thus, the present invention provides a method for forming a contact window in a semiconductor device 10 without having to use a photo mask. Specifically, the undeveloped photo resist layer over the substrate can act as a mask so that unwanted portions of the passivation layer (i.e., over pad metal 14) can be removed. As indicated above, the present invention can be applied to any known semiconductor device in which a window contact is formed, (i.e., in which a pad metal is exposed). For example, the present invention could be applied during the fabrication of a Schottky barrier diode 50 such as that shown in FIG. 7. As depicted, diode 50 includes silicon carbide substrate 52, oxide layer 54 positioned over substrate 52, pad metal 56 mounted on substrate, and passivation layer 60 positioned over oxide layer 54. Passivation layer 60 could have been removed over pad metal 56, to expose top surface 58, using the methodology of the present invention.

### EXAMPLE

The present invention was embodied in the following example. A semiconductor device having a substrate, a shiny patterned aluminum pad metal, and an oxide passivation layer was provided. A photo resist layer having a thickness of approximately 1 Πm was spun over the passivation layer and then patterned by subjecting the layer, via flooding, to ultraviolet light for approximately nine seconds. The developed portion of the photo resist was then etched in a diluted developer solution of OCG-934, 3:2 developer:water to reveal the passivation layer over the pad metal. The remaining photo resist (i.e., the undeveloped portion) over the substrate was then hard baked for thirty minutes at 140° C. and the revealed oxide passivation layer over the pad metal was removed with buffered hydrogen fluoride. Lastly, the hard baked photo resist over the substrate was removed using the organic solution NMP.

The foregoing description of the preferred embodiments of this invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of this invention as defined by the accompanying claims.

1. A method for forming a contact window in a semiconductor device having a substrate, a pad metal mounted on the substrate, and a passivation layer positioned over both the pad metal and the substrate, comprising the steps of:
applying a photo resist layer over the passivation layer;
developing a portion of the applied photo resist layer using ultraviolet light;
etching away the developed portion to reveal the passivation layer over the pad metal; and
forming a contact window by removing the revealed passivation layer.

2. The method of claim 1, wherein the patterning step comprises the steps of:
developing a portion of the applied photo resist layer by flood exposing the photo resist layer to ultraviolet light; and
etching away the developed portion to reveal the passivation layer over the pad metal.

3. The method of claim 2, wherein the etching step comprises the step of etching away the developed portions using a developer.

4. The method of claim 1, wherein the forming step comprises the steps of:
baking the patterned photo resist layer over the substrate; and
forming a contact window by removing the revealed passivation layer over the pad metal.

5. The method of claim 1, wherein the revealed passivation layer is removed using hydrogen fluoride.

6. The method of claim 1, further comprising the step of removing the patterned photo resist layer over the substrate.

7. The method of claim 6, wherein the patterned photo resist layer is removed using an organic solution.

8. A method for forming a contact window in a semiconductor device, comprising the steps of:
providing a semiconductor device having a substrate, a pad metal mounted on the substrate, and a passivation layer positioned over both the substrate and the pad metal;
applying a photo resist layer over the passivation layer;
developing a portion of the applied photo resist layer using incident ultraviolet light and its reflection from the pad metal;
etching away the developed portion to reveal the passivation layer over the pad metal; and
forming a contact window by removing the revealed passivation layer over the pad metal.

9. The method of claim 8, further comprising the step of removing the photo resist layer over the substrate using an organic solution.

10. The method of claim 8, wherein the etching step comprises the step of etching away the developed portion over the pad metal using a developer.

11. The method of claim 8, wherein revealed passivation layer over the pad metal is removed using hydrogen fluoride.

12. The method of claim 8, wherein the forming step comprises the steps of:
baking the photo resist layer over the substrate; and
forming a contact window by removing the revealed passivation layer over the pad metal.

13. The method of claim 8, wherein the developing step comprises the step of flood exposing the photo resist layer with ultraviolet light for a predetermined period of time that is dependent upon a thickness of the photo resist layer and a difference in reflection coefficient of the substrate and the pad metal.

14. A method for forming a contact window in a semiconductor device, comprising the steps of:
providing a semiconductor device having a substrate, a pad metal mounted on the substrate, and a passivation layer over both the substrate and the pad metal;
applying a photo resist layer over the passivation layer;
developing a portion of the applied photo resist layer using incident ultraviolet light and its reflection from the pad metal;
etching away the developed portions to reveal the passivation layer over the pad metal;
baking an undeveloped portion of the photo resist layer;
forming a contact window by removing the revealed passivation layer over the pad metal; and
removing the baked portion of the photo resist layer.

15. The method of claim 14, wherein the applied photo resist layer is approximately 1 μm thick, and wherein the developing step comprises the step of flood exposing the photo resist layer to ultraviolet light for approximately nine seconds.

16. The method of claim 14, wherein the baked photo resist layer is over the substrate and is removed using an organic solution.

17. The method of claim 14, wherein the passivation layer over the pad metal is removed using hydrogen fluoride.

18. A method for forming a contact window in a semiconductor device, comprising the steps of:
providing a semiconductor device having a substrate, a pad metal mounted on the substrate, and a passivation layer over both the substrate and the pad metal;
applying a photo resist layer over the passivation layer;
developing a portion of the applied photo resist layer using ultraviolet light for a predetermined period of time, wherein the predetermined period of time is based upon a thickness of the photo resist layer and a difference in reflection coefficients of the pad metal and the substrate;
etching away the developing portion to expose the passivation layer over the pad metal;
baking an undeveloped portion of the photo resist layer over the substrate;
forming a contact window by removing the passivation layer over the pad metal; and
removing the baked portion over the substrate.

19. The method of claim 18, wherein the predetermined thickness is approximately 1 μm.

20. The method of claim 18, wherein the predetermined time is approximately nine seconds.
